(19) United States
(12) Patent Application Publication
(10) Pub. No.: US 2010/0151127 A1
(43) Pub. Date: Jun. 17, 2010

(54) APPARATUS AND METHOD FOR PREVENTING PROCESS SYSTEM CONTAMINATION

(75) Inventors: Tom K. Cho, Los Altos, CA (US); Lun Tsuei, Mountain View, CA (US); Kuan-Yuan Peng, San Jose, CA (US); Kyle S. Reinke, Angels Camp, CA (US); Brian Sy-Yuan Shieh, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/628,034

(22) Filed: Nov. 30, 2009

Related U.S. Application Data
(60) Provisional application No. 61/122,229, filed on Dec. 12, 2008.

(51) Int. Cl. C23C 16/52; C23C 16/00

(52) U.S. Cl. 427/248.1; 118/712; 118/663

(57) ABSTRACT

Embodiments of the present invention generally provide apparatus and methods for preventing contamination within a processing system due to substrate breakage. In one embodiment, an acoustic detection mechanism is disposed on or within a process chamber to monitor conditions within the process chamber. In one embodiment, the acoustic detection mechanism detects conditions indicative of substrate breakage within the process chamber. In one embodiment, the acoustic detection mechanism detects conditions that are known to lead to substrate breakage within the process chamber. In one embodiment, the acoustic detection mechanism is combined with an optical detection mechanism. By early detection of substrate breakage or conditions known to lead to substrate breakage, the process chamber may be taken off line and repaired prior to contamination of the entire process system.

### CROSS-REFERENCE TO RELATED APPLICATIONS

This application claims benefit of U.S. provisional patent application Ser. No. 61/122,229, filed Dec. 12, 2008, which is herein incorporated by reference.

### BACKGROUND OF THE INVENTION

1. Field of the Invention

Embodiments of the present invention provide apparatus and methods for preventing substrate process system contamination due to substrate breakage.

2. Description of the Related Art

As demand for larger solar panels and flat panel displays continues to increase, so must the size of substrates, process chambers, and process systems for processing the substrates. In processing substrates for solar panels or flat panel displays, sequential layers of thin films are deposited onto substrates in one or more deposition chambers arranged in a process system or cluster. Substrates are transferred into processing systems and between deposition chambers in order to deposit the sequential layers of thin films necessary during the manufacture of solar panels of flat panel displays.

As substrate sizes increase, substrate handling becomes increasingly difficult. However, maintenance of a contaminant free environment within the process chamber remains critical. Therefore, there is a need for an apparatus and method for preventing contamination in a substrate processing system due to substrate breakage.

### SUMMARY OF THE INVENTION

In one embodiment of the present invention, a processing apparatus comprises a processing chamber having walls, a bottom, a showerhead, and a substrate support defining a process volume, a plurality of substrate support members, each disposed through the substrate support, and an acoustic monitoring device configured to monitor substrate handling and processing conditions within the processing chamber.

In another embodiment of the present invention, a processing chamber comprises a plurality of walls, a bottom, and a lid with a processing volume confined therein, a substrate support having a plurality of substrate support pins disposed therethrough, wherein the substrate support is disposed in the processing volume of the processing chamber, and an acoustic monitoring device positioned proximate the substrate support and configured to monitor sounds within the processing chamber.

In yet another embodiment of the present invention, a method of preventing contamination in a processing system comprises capturing an acoustic signature of processing a substrate in a process chamber to define an acceptable acoustical range, monitoring sounds within the process chamber while a substrate is processed, comparing the monitored sounds with the acceptable acoustical range, and determining whether a contamination condition exists within the process chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top schematic view of one embodiment of a processing system.

FIG. 2 is a schematic, cross-sectional view of one embodiment of a process chamber according to the present invention.

FIG. 3A depicts an embodiment of a process chamber in a substrate processing position according to one embodiment of the present invention.

FIG. 3B depicts an embodiment of the process chamber depicted in FIG. 3A in a substrate transfer position.

FIG. 4A is a schematic view of one embodiment of a support member, which may be used in place of lift pins in the process chamber depicted in FIGS. 3A and 3B.

FIG. 4B is a schematic view of one embodiment of a busing used in the support member depicted in FIG. 4A.

FIG. 4C is a schematic view of one embodiment of the bearing elements shown in FIG. 4A.

FIG. 4D is a partial cross-sectional view of the bearing elements depicted in FIGS. 4A and 4C.

FIG. 5 is a schematic, cross-sectional view of a process chamber 500 according to another embodiment of the present invention.

### DETAILED DESCRIPTION

Embodiments of the present invention generally provide apparatus and methods for preventing contamination within a processing system due to substrate breakage. In one embodiment, an acoustic detection mechanism is disposed on or within a process chamber to monitor conditions within the process chamber. In one embodiment, the acoustic detection mechanism detects conditions indicative of substrate breakage within the process chamber. In one embodiment, the acoustic detection mechanism detects conditions that are known to lead to substrate breakage within the process chamber. In one embodiment, the acoustic detection mechanism is combined with an optical detection mechanism. By early detection of substrate breakage or conditions known to lead to substrate breakage, the process chamber may be taken off line and repaired prior to contamination of the entire process system. Thus, system down time is minimized because only the contaminated process chamber need be shut down, while the remainder of the processing system continues production.

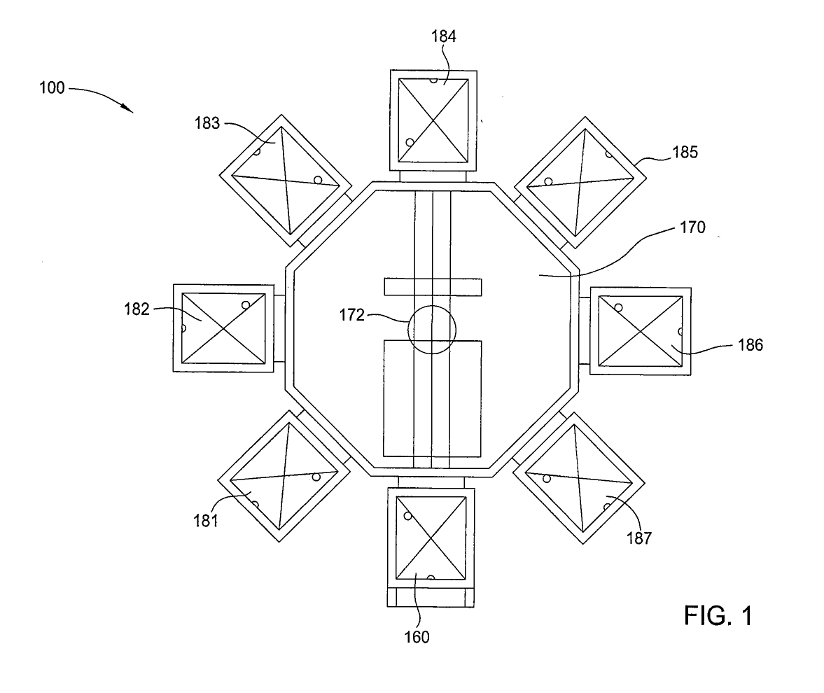

FIG. 1 illustrates a processing system 100 that may benefit from the present invention. FIG. 1 is a top schematic view of one embodiment of a processing system 100. The processing system 100 includes a plurality of process chambers 181-187 capable of depositing one or more desired layers on a substrate surface. The process system 100 may include a transfer chamber 170 coupled to a load lock chamber 160 and the process chambers 181-187. The load lock chamber 160 allows substrates to be transferred between the ambient environment outside the system and vacuum environment within the transfer chamber 170 and process chambers 181-187. The load lock chamber 160 includes one or more evacuatable regions holding one or more substrates. The evacuatable regions are pumped down during input of substrates into the system 100 and are vented during output of the substrates from the system 100. The transfer chamber 170 has at least one transfer robot 172 disposed therein that is adapted to transfer substrates between the load lock chamber 160 and the process chambers 181-187. While seven process chambers are shown in FIG. 1, the system 100 may have any suitable number of process chambers.

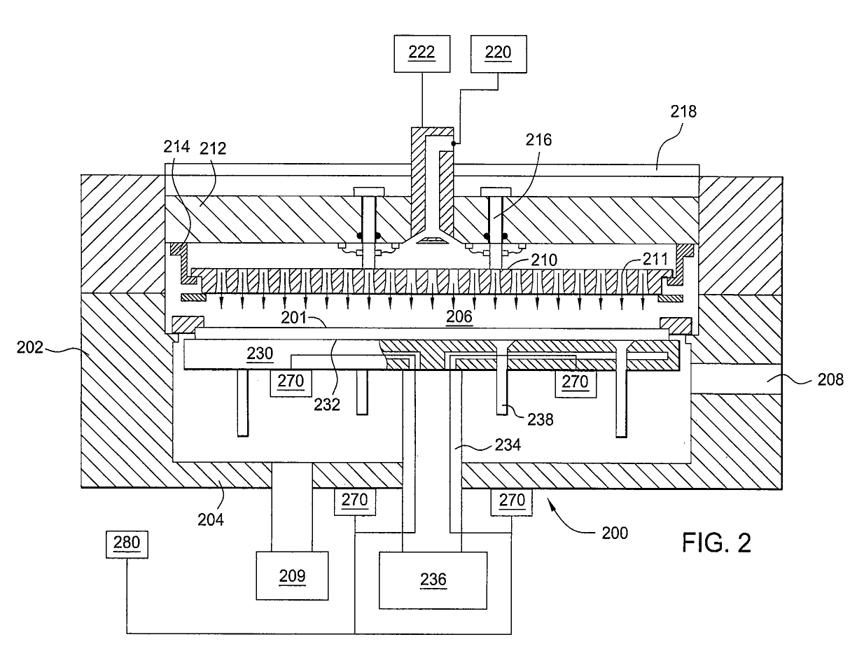

FIG. 2 is a schematic, cross-sectional view of one embodiment of a process chamber 200 according to the present invention. The process chamber 200 may correspond to any of the process chambers 181-187 depicted in FIG. 1. One suitable process chamber 200 is a plasma enhanced chemical vapor deposition (PECVD) chamber available from Applied Materials, Inc., located in Santa Clara, Calif. It is contemplated that other process chambers, such as hot wire chemical vapor deposition (HWCVD), low pressure chemical vapor deposition (LPCVD), physical vapor deposition (PVD), evaporation, or other similar devices, including those from other manufacturers, may be utilized to practice the present invention.

In one embodiment, the process chamber 200 includes walls 202, a bottom 204, a showerhead 210, and a substrate support 230, which cumulatively define a process volume 206. The showerhead 210 may be coupled to a backing plate 212 at its periphery by a suspension 214. The showerhead 210 may also be coupled to the backing plate 212 by one or more center supports 216 to help prevent sag and/or control the straightness/curvature of the showerhead 210.

In one embodiment, a gas source 220 is coupled to the backing plate 212 to provide gas through the backing plate 212 and through the plurality of holes 211 in the showerhead 210 into the process volume 206. A vacuum pump 209 may be coupled to the process chamber 200 to control the process volume 206 at a desired pressure. An RF power source 222 may be coupled to the backing plate 212 to provide RF power to the showerhead 210 so that an electric field is created between the showerhead 210 and the substrate support 230 so that plasma may be generated from the gases between the showerhead 210 and the substrate support 230.

In one embodiment, the process volume 206 is accessed through a valve opening 208 such that a substrate 201 may be transferred into and out of the process chamber 200. The substrate support 230 may include a substrate receiving surface 232 for supporting the substrate 201 and stem 234 coupled to a lift system 236 to raise and lower the substrate support 230. In one embodiment, lift pins 238 are moveably disposed through the substrate support 230 to move a substrate to and from the substrate receiving surface 232.

In one embodiment, one or more acoustic detection devices 270 may be disposed on or in the chamber 200. In one embodiment, one or more acoustic detection devices 270 are disposed adjacent the chamber bottom 204. In one embodiment, one or more acoustic detection devices 270 are disposed adjacent the chamber walls 202. In one embodiment, one or more acoustic detection devices 270 are disposed adjacent the chamber cover 218. In one embodiment, acoustic detection devices 270 may be disposed within the chamber 200. In one embodiment, acoustic detection devices may be attached to an underside of the substrate support 230. In one embodiment, the acoustic detection devices 270 may be attached to the outside of the chamber 200.

In one embodiment, the acoustic detection device 270 comprises a microphone capable of detecting an acoustic range encompassing the sounds generated during processing a substrate in the process chamber 200. In one embodiment, the acoustic detection device is connected to a controller 280.

The controller 280 may include a central processing unit (CPU) (not shown), memory (not shown), and support circuits (or I/O) (not shown). The CPU may be one of any form of computer processors that are used in industrial settings for controlling various system functions, substrate movement, chamber processes, and support hardware, and monitor the processes. The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. In one embodiment, the controller 280 encompasses software instructions, such as acoustic software, as well as one or more recording devices for capturing acoustic conditions within the process chamber 200.

In one embodiment, the controller 280 is programmed with an acoustic signature associated with normal operational conditions including the transfer of the substrate 201 into the process chamber 200, the processing of the substrate 201 within the process chamber 200, and the transfer of the substrate 201 out of the process chamber 200. In one embodiment, the initial acoustic signature of the above operations may be captured by the acoustic detection device 270. In operation, the acoustic detection device 270 monitors the processing of each substrate 201, while communicating with the controller 280. If sounds generated during the processing of the substrate 201 remain within the expected acoustic range, processing continues as normal. However, if sounds are detected outside of the expected acoustic range, such as a sound indicating substrate breakage, the system may be shut down for inspection and repair of the process chamber 200. Thus, potential contamination of transfer or other process chambers within the same processing system as process chamber 200 may be prevented.

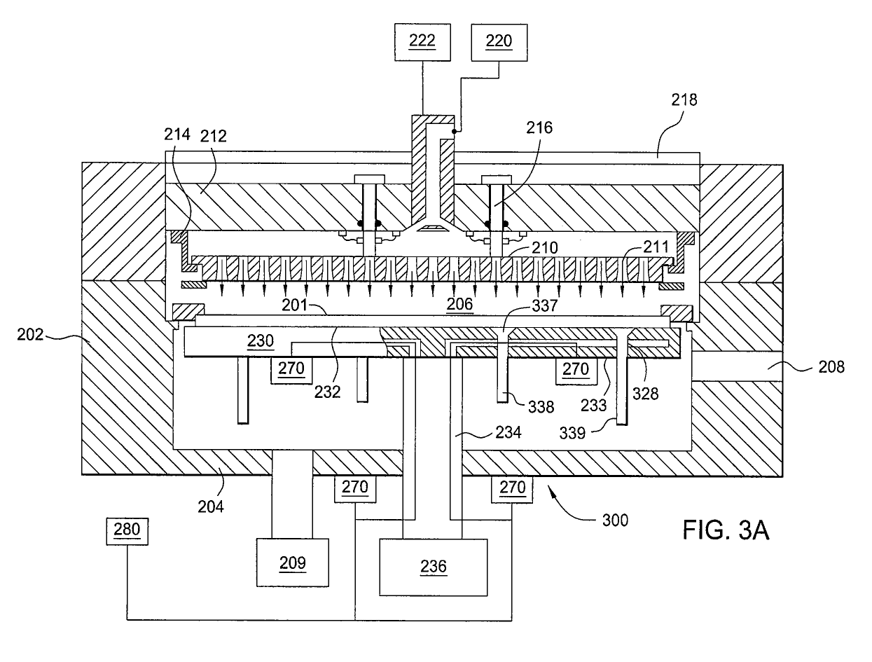

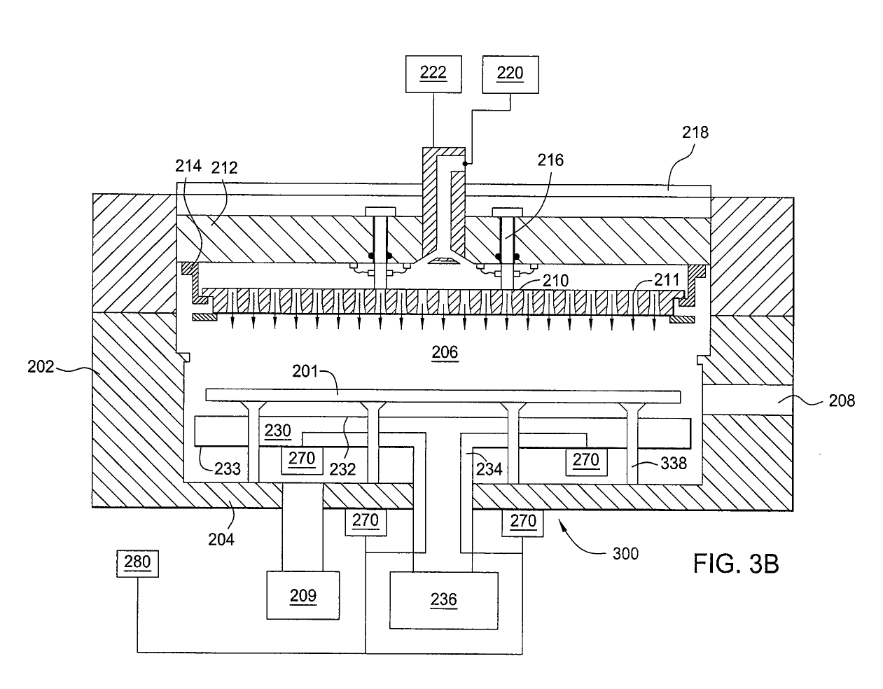

FIGS. 3A and 3B depict a process chamber 300 according to one embodiment of the present invention. The process chamber 300 is similar to the process chamber 200 depicted in FIG. 2, and as such, identical reference numbers are shown to reflect identical chamber parts without further description. In one embodiment, the process chamber 300 may have lift pins 338 disposed at least partially within the substrate support 230. In this embodiment, the substrate support 230 includes a plurality of holes 328 disposed therethrough. The lift pins 338 are correspondingly disposed at least partially within the holes 328. Acoustic detection devices 270 may be disposed within and/or outside of the chamber 300, each connected to the controller 280. In one embodiment, one or more acoustic detection devices 270 are placed in close proximity to the lift pins 338, such as attached to a lower side 233 of the substrate support 230. In another embodiment, one or more acoustic detection devices 270 are attached to a lower side of the chamber bottom 204 of the process chamber 300.

FIG. 3A depicts an embodiment of the process chamber 300 in a substrate processing position. In one embodiment, an upper end 337 of each lift pin 338 is substantially flush with or slightly recessed from the receiving surface 232 of the substrate support 230 when the substrate support 230 is in a raised or substrate processing position. Correspondingly, a second end 339 of each lift pin 338 extends beyond the lower side 233 of the substrate support 230.

FIG. 3B depicts an embodiment of the process chamber 300 in a substrate transfer position. As the substrate support 230 is lowered into the substrate transfer position, the lift pins 338 contact the bottom 204 of the chamber 300 and are displaced through the substrate support 230 to project upwardly from the substrate receiving surface 232 of the substrate support 230. As a result, the substrate 201 may be positioned atop the lift pins 338 in a spaced apart relation to the substrate support 230 to allow a transfer robot, such as transfer robot 172 (FIG. 1), access to the bottom side of the substrate 201 for subsequent transfer.

Certain conditions that may cause substrate breakage in the process chamber 300 involve the binding of one or more of the lift pins 338 in either the substrate transfer position or the substrate processing position. In one of these conditions, one or more of the lift pins 338 may bind as the substrate support 230 is lowered into the substrate transfer position. As the substrate support 230 continues to lower, the binding lift pin 338 may bend or break. As a result, the substrate 201 positioned atop the lift pins 338 may be damaged due to uneven support forces supplied by the lift pins 338. If not detected, the damaged substrate 201, or portions thereof, may subsequently be transferred into a transfer chamber, such as transfer chamber 170 (FIG. 1), causing additional process system contamination.

Further, when a new substrate is placed onto the lift pins 338 within the process chamber 300, the new substrate may be damaged due to uneven support forces supplied by the lift pins 338. Subsequently, the substrate support 230 may be raised to support the new substrate. If the damaged lift pin 338 is either stuck in its “up” position or broken, and a portion thereof lying on the support surface 232 of the substrate support 230, the substrate 201 may have a point load exerted thereon and subsequently break. Again, if not detected or prevented, subsequent transfer of the damaged or broken substrate into the processing system may cause additional process system contamination and/or damage, resulting in significant downtime and expense.

However, the one or more acoustic detection devices 270 may not only be used to detect the sound of the substrate breakage and prevent subsequent transfer and contamination of the process system, but it may also be used to detect the sound of the lift pin 338 binding, squeaking, sticking, or breaking prior to the ultimate breakage of the substrate 201. In one embodiment, the controller 280 is programmed with the acoustic range of normal processing of the substrate 201, which may be initially captured using the acoustic detector 270 during normal substrate handling and processing. Once the “out of range” sound of a binding lift pin 338 is detected, the process may be interrupted, and the process chamber 300 taken off line for inspection and repair. Thus, the acoustic detection device 270 may be used to prevent substrate breakage, in turn, preventing subsequent process system contamination.

In one embodiment, a plurality of acoustic detection devices 270 may be monitored to determine if acoustic signatures throughout processing are recorded simultaneously. If a lag in detecting acoustic signatures of the processing sequence is detected, further diagnostic procedures may be needed to determine if one or more of the acoustic detection devices 270 is functioning properly.

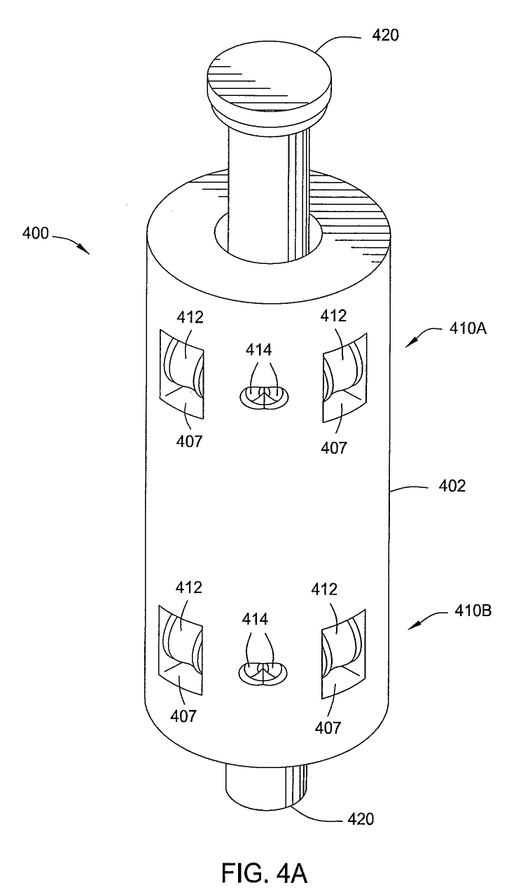

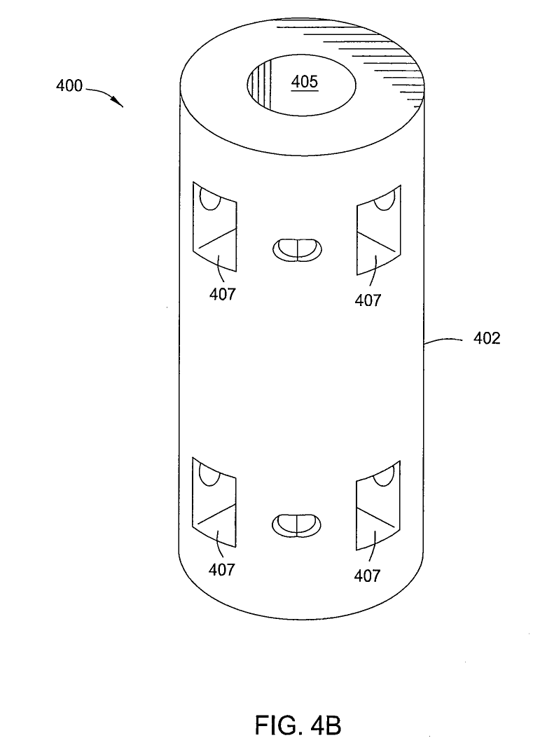

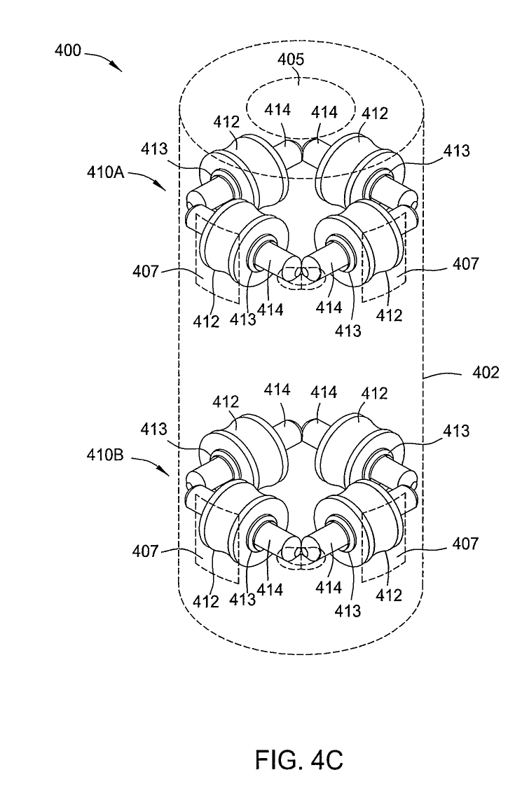

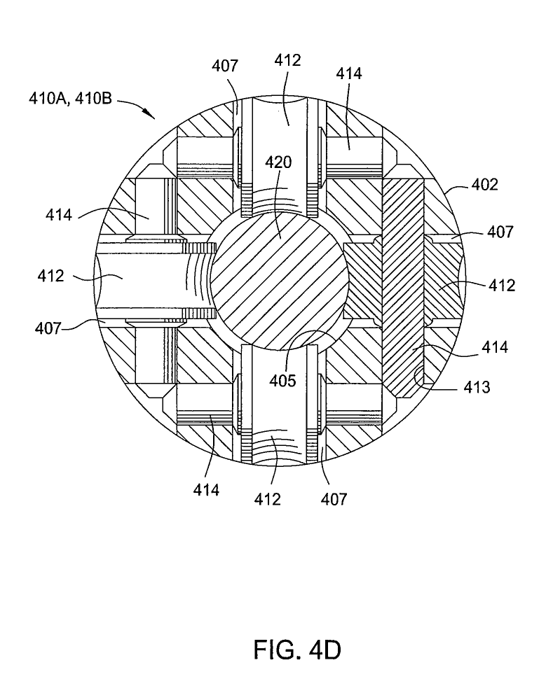

FIG. 4A is a schematic view of one embodiment of a support member 400, which may be used in holes 328 of the process chamber 300 in place of the lift pins 338 depicted in FIGS. 3A and 3B. In one embodiment, the support member 400 includes a bushing 402 having one or more bearing elements 410A, 410B and a support pin 420 at least partially disposed therein. At a first end of the support pin 420, a substrate (not shown), such as substrate 201, is supported thereon. At a second end of the support pin 420, the support member 400 is disposed on an upper surface of a chamber bottom, such as the chamber bottom 204 of the process chamber 300.

FIG. 4B is a schematic view of one embodiment of the bushing 402. The bushing 402 may be an annular member having a central bore 405 and one or more windows 407 formed therethrough. The bushing 402 may resemble a cylindrical tube. In one embodiment, the bushing 402 includes a first set of windows 407 located at a first end thereof and a second set of windows 407 located at a second end thereof.

FIG. 4C is a schematic view of one embodiment of the bearing elements 410A, 410B shown in FIG. 4A. FIG. 4D is a partial cross-sectional view of the bearing elements 410A, 410B. Referring to FIGS. 4C and 4D, the first bearing element 410A is housed within the first set of windows 407 at least partially formed through the first end of the bushing 402. The second bearing element 410B is housed within the second set of windows 407 at least partially formed through the second end of the bushing 402.

In one embodiment, each bearing element 410A, 410B includes one or more rollers 412 having a central bore 413 formed therethrough and a shaft 414 disposed at least partially through the central bore 413. The shaft 414 is secured to the bushing 402 to hold the roller 412 in place. In one embodiment, the ends of each shaft 414 are chamfered to form a conical shape as shown in FIG. 4C. Upon installation of the bearing elements 410A, 410B, within the bushing 402, the rollers 412 are held into place via a friction fit facilitated by the ends of the shafts 414 arranged opposite one another.

The bearing elements 410A, 410B support the support pin 420 within the bushing 402. The bearing elements 410A, 410B also allow the support pin 420 to move axially through the bore 405 of the bushing 402 and rotate within the bore 405 with minimal resistance.

However, if one or more of the shafts 414 become damaged or if the bore 405 becomes contaminated, the support pin 420 may bind or otherwise operate erratically. As a result, the substrate, such as substrate 201, being supported atop the support pin 420 may become damaged or broken. Again, if not detected, the damaged substrate, or portions thereof, may be transferred into other chambers, resulting in contamination of the processing system.

In one embodiment of the present invention, one or more acoustic detection devices 270, connected to the controller 280, may be positioned to monitor sounds associated with the operation of the support member 400. The controller 280 may be programmed with the acoustic range of a normally functioning support member 400, which may be initially captured by the acoustic detection devices 270. The acoustic detection device 270 may then monitor the operating conditions of each substrate transferred into the process chamber 300, processed in the process chamber 300, and removed from the process chamber 300. If the acoustic detection device 270 detects out of range sounds, such as that associated with a misaligned, binding, squeaking or broken shaft 414, the process chamber 300 may be taken off line, inspected, and repaired prior to causing any substrate breakage. Thus, the acoustic detection device 270 may prevent contamination to the process system comprising the process chamber 300.

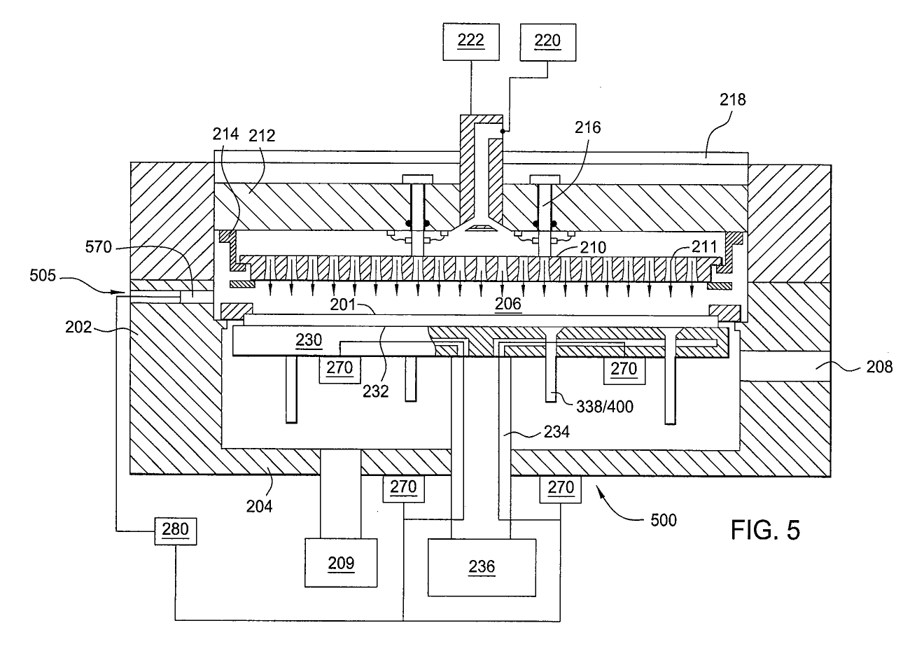

FIG. 5 is a schematic, cross-sectional view of a process chamber 500 according to another embodiment of the present invention. The process chamber 500 is similar to the process chambers 200 and 300 depicted in FIGS. 2, 3A, and 3B, and as such, identical reference numbers are shown to reflect identical chamber parts without further description.

In one embodiment, the process chamber 500 includes the acoustic detection device 270 connected to the controller 280 for monitoring the acoustic signature of processing conditions within the process chamber 500. In one embodiment, the process chamber 500 also includes an optical detection device 570 positioned to monitor the processing conditions within the process chamber 500. The optical detection device 570 may be connected to the controller 280, which may include additional optical software and recording devices as well as acoustic software and recording devices. As such, optical conditions monitored by the optical detection device 570 may be correlated with the acoustic conditions monitored by the acoustic detection device 270 to provide a complete signature of processing conditions within the processing chamber 500.

In one embodiment, the optical detection device 570 is a camera for continuously monitoring optical conditions in the process chamber 500. The optical detection device 570 may be positioned inside or outside of the process chamber 500. In one embodiment, the optical detection device 570 is positioned outside of the process chamber 500 and aimed through a viewing window 505 in the wall 202 of the process chamber 500. In one embodiment, the optical detection device 570 is positioned to monitor the general operation of the substrate support 230 and either the lift pins 338 or support members 400 provided therein. Additionally, the optical detection device 570 is positioned to monitor the condition of the substrate 201 as it is transferred into the process chamber 500, processed in the process chamber 500, and removed from the process chamber 500. In one embodiment, the optical detection device 570 includes a lighting device for illuminating the interior of the chamber 500. In one embodiment, the lighting source emits light in a visible wavelength range. In another embodiment, the lighting source emits light in a non-visible wavelength range.

In operation, the optical detection device 570 and the acoustic detection device 270 combine to provide more complete monitoring of processing conditions and detection of conditions that may lead to substrate breakage. In one embodiment, the optical detection device 570 may capture an initial optical signature of normal conditions within the process chamber 500 associated with handling and processing of the substrate 201 within the process chamber 500. This initial optical signature may be programmed into the controller 280 and correlated with an initial acoustic signature of the identical processes captured by the acoustic detection device 270. Subsequently, both the optical detection device 570 and the acoustic detection device 270 continue to monitor conditions within the process chamber 500 for each substrate processed. If all sounds produced remain within an acceptable range, the processing continues as normal. However, if sounds are detected outside of the acceptable acoustic range, optical images captured by the optical detection device 570 may be reviewed and monitored to determine whether the process chamber 500 should be taken offline and repaired to prevent substrate breakage and contamination of the process system. Thus, the optical detection device 570 may provide additional information that may be correlated with the acoustic information provided by the acoustic detection device 270 to determine whether conditions exist that may cause substrate breakage prior to any substrate damage or breakage occurring. Therefore, downtime of both the process chamber 500 and the processing system may be minimized.

Therefore, embodiments of the present invention provide apparatus and methods for preventing contamination within a processing system due to substrate breakage through acoustic monitoring or optical and acoustic monitoring of a process chamber during substrate handling and processing.

While the foregoing is directed to embodiments of the present invention, other and further embodiments of the invention may be devised without departing from the basic scope thereof, and the scope thereof is determined by the claims that follow.

1. A processing apparatus, comprising:
a processing chamber having walls, a bottom, a showerhead, and a substrate support defining a process volume;
a plurality of substrate support members, each disposed through the substrate support; and
an acoustic monitoring device configured to monitor substrate handling and processing conditions within the processing chamber.

2. The processing apparatus of claim 1, wherein the acoustic monitoring device comprises a microphone positioned to monitor movement of the substrate support members.

3. The processing apparatus of claim 2, further comprising a controller connected to the acoustic monitoring device.

4. The processing apparatus of claim 3, wherein the controller comprises acoustic software and an acoustic recording device.

5. The processing apparatus of claim 4, wherein the acoustic monitoring device is disposed outside of the processing chamber.

6. The processing apparatus of claim 4, wherein the acoustic monitoring device is attached to an underside of the substrate support.

7. The processing apparatus of claim 4, further comprising an optical monitoring device configured to monitor substrate handling and processing conditions within the processing chamber.

8. The processing apparatus of claim 7, wherein the optical monitoring device comprises a camera and a lighting mechanism.

9. The processing apparatus of claim 8, wherein the optical monitoring device is positioned inside the processing chamber.

10. The processing apparatus of claim 8, wherein the optical monitoring device is attached to a wall of the processing chamber.

11. A processing chamber, comprising:
a plurality of walls, a bottom, and a lid with a processing volume confined therein;
a substrate support having a plurality of substrate support pins disposed therethrough, wherein the substrate support is disposed in the processing volume of the processing chamber;
an acoustic monitoring device positioned proximate the substrate support and configured to monitor sounds within the processing chamber.

12. The processing chamber of claim 11, further comprising an optical monitoring device positioned proximate the processing volume and configured to monitor substrate handling and processing within the processing chamber.

13. The processing chamber of claim 12, further comprising a controller connected to the acoustic monitoring device and the optical monitoring device.

14. The processing chamber of claim 13, wherein the controller further comprises acoustic software, optical software, and a recording device.

15. The processing chamber of claim 14, wherein the acoustic monitoring device comprises a microphone disposed within the processing chamber and the optical monitoring device comprises a camera and a lighting device.

16. The processing chamber of claim 14, wherein the acoustic monitoring device comprises a microphone attached to the bottom of the processing chamber and the optical monitoring device comprises a camera and a lighting device.

17. A method of preventing contamination in a processing system, comprising:
capturing an acoustic signature of processing a substrate in a process chamber to define an acceptable acoustical range;
monitoring sounds within the process chamber while a substrate is processed;
comparing the monitored sounds with the acceptable acoustical range; and
determining whether a contamination condition exists within the process chamber.

18. The method of claim 17, wherein processing the substrate further comprises loading the substrate into the process chamber and removing the substrate from the process chamber.

19. The method of claim 18, further comprising monitoring sounds within the process chamber while the substrate is being loaded into the process chamber.

20. The method of claim 19, further comprising monitoring sounds within the process chamber while the substrate is being removed from the process chamber.

21. The method of claim 20, wherein determining whether a contamination condition exists comprises detecting sounds outside of the acceptable acoustic range.

22. The method of claim 21, further comprising taking the process chamber offline if a contamination condition exists.

23. The method of claim 22, further comprising optically monitoring the process chamber while the substrate is being processed.

24. The method of claim 23, further comprising optically monitoring the process chamber while the substrate is being transferred into the process chamber.

25. The method of claim 24, further comprising optically monitoring the process chamber while the substrate is being removed from the process chamber.
